(19) United States
(12) Patent Application Publication
(10) Pub. No.: US 2024/0404787 A1
(43) Pub. Date: Dec. 5, 2024

(54) ION IMPLANTER AND ION IMPLANTATION METHOD

(71) Applicant: NISSIN ION EQUIPMENT CO., LTD., Koka-city (JP)

(72) Inventors: Yuya HIRAI, Koka-city (JP); Weijiang Zhao, Koka-city (JP); Shunsuke Omura, Koka-city (JP); Akihito Nakanishi, Koka-city (JP); Takumi Sato, Koka-city (JP)

(73) Assignee: NISSIN ION EQUIPMENT CO., LTD., Koka-city (JP)

(21) Appl. No.: 18/612,254

(22) Filed: Mar. 21, 2024

(30) Foreign Application Priority Data
May 30, 2023 (JP) 2023-89053

(51) Int. Cl. H01J 37/317; H01J 37/08; H01J 37/147; H01J 37/20

(52) U.S. Cl. CPC H01J 37/3171; H01J 37/08; H01J 37/1471; H01J 37/20; H01J 2237/31701

(57) ABSTRACT

An ion implanter includes an angle measurement apparatus that measures a first angle of an ion beam in a first direction and a second angle of the ion beam in a second direction, the first direction and the second direction being mutually orthogonal to a traveling direction of the ion beam, an angle corrector that is located in a beamline of the ion beam and corrects an angle of the ion beam in the first direction based on the first angle, a wafer holder that holds a wafer in a process chamber, a tilt device that is connected to the wafer holder and that rotates the wafer around a rotation axis parallel to the first direction, and a controller that controls the tilt device based on the second angle, crystal axis information of the wafer, and implantation recipe information.

### CROSS-REFERENCE TO RELATED APPLICATION

This Application claims priority to Japanese Application No. 2023-089053,filed May 30, 2023 in the Japan Patent Office, the contents of which being herein incorporated by reference in its entirety.

### BACKGROUND

The present disclosure relates to an ion implanter and ion implantation method for manufacturing semiconductor devices.

In an ion implantation process, an irradiation angle of an ion beam irradiated to a wafer surface is set to desired angle. For example, when using channeling ion implantation to implant ions from the wafer surface into a deeper area of the wafer, the irradiation angle of the ion beam is set so that an irradiation direction of the ion beam matches a crystal axis of the wafer. Conversely, when implanting ions into a shallow area from the wafer surface, the ion beam irradiation angle is set so that the ion beam irradiation direction does not coincide with the crystal axis of the wafer.

If manufacturing errors occur in a wafer manufacturing process, such as in a slicing process and/or a polishing process, a flatness of the wafer will be low. The crystal axis of the wafer is perpendicular to the wafer surface. However, a decreased flatness of the wafer can result in a mismatch between the ion beam irradiation direction and the crystal axis, even if a direction of the ion beam is perpendicular to the wafer surface.

An epitaxial silicon carbide wafer is a wafer on which an epitaxial layer is deposited on a base wafer. The epitaxial layer is deposited at an inclination of about 4 degrees with respect to the wafer plane of the base wafer for the purpose of suppressing defects in the epitaxial layer. Due to the inclination of the epitaxial layer, the direction of the crystal axis (i.e., a crystal orientation) of the wafer is inclined about 4 degrees from the wafer plane of the base wafer.

Therefore, even if there were no manufacturing errors in the slicing process and/or the polishing process, the crystal orientation is not perpendicular to the wafer plane of the base wafer in the epitaxial silicon carbide wafer.

As a related art method, various techniques have been proposed to adjust the relationship between the crystal orientation of the wafer and the ion beam irradiation direction.

### SUMMARY

According to an aspect of one or more embodiments, there is provided an ion implanter comprising an angle measurement apparatus that measures a first angle of an ion beam in a first direction and a second angle of the ion beam in a second direction, the first direction and the second direction being mutually orthogonal to a traveling direction of the ion beam; an angle corrector that is located in a beamline of the ion beam and corrects an angle of the ion beam in the first direction based on the first angle; a wafer holder that holds a wafer in a process chamber; a tilt device that is connected to the wafer holder and that rotates the wafer around a rotation axis parallel to the first direction; and a controller that controls the tilt device based on the second angle, crystal axis information of the wafer, and implantation recipe information.

According to yet another aspect of one or more embodiments, there is provided an ion implantation method comprising measuring a first angle of an ion beam in a first direction and a second angle of the ion beam in a second direction, the first direction and the second direction being mutually orthogonal to a traveling direction of the ion beam; correcting an angle of the ion beam in the first direction based on the first angle; rotating the wafer with the first direction as a rotation axis based on the second angle, crystal axis information of the wafer, and implantation recipe information, and implanting ions into the wafer.

According to yet another aspect of one or more embodiments, there is provided an ion implanter comprising a plasma chamber; one or more extraction electrodes that extract an ion beam from the plasma chamber; a process chamber comprising a wafer holder and a tilt device; an angle measurement apparatus that measures angles of the ion beam in two directions that are mutually orthogonal to a traveling direction of the ion beam; an angle corrector that is located in a beamline of the ion beam and corrects an angle of the ion beam in one of the two directions based on the measured angle in the one of the two directions, the beamline being a transport path of the ion beam from the one or more extraction electrodes to the process chamber; and a controller that controls the tilt device based on the measured angle in the other of the two directions, crystal axis information of the wafer, and implantation recipe information to correct an angle of the ion beam in the other of the two directions.

### BRIEF DESCRIPTION OF THE DRAWINGS

The above and/or other aspects will become apparent and more readily appreciated from the following description of various embodiments, taken in conjunction with the accompanying drawings, in which:

FIG. 1 is a schematic plan view of an example of an ion implanter, according to some embodiments;

FIG. 2-4 illustrate an example of angle measurement in an X-axis direction, according to some embodiments;

FIG. 5 illustrates an example of angle correction in the X-axis direction, according to some embodiments;

FIGS. 6 illustrates an examples of an ideal ion beam trajectory and an actual ion beam trajectory, according to various embodiments.

FIGS. 7-9 illustrate an example of angle measurement in a Y-axis direction, according to some embodiments;

FIG. 10 is a schematic cross-sectional view of an example of a tilt device for adjusting an orientation of a wafer in the Y-axis direction, according to some embodiments;

FIG. 11 is a schematic plan view of an example of a crystal axis measurement apparatus, according to some embodiments;

FIG. 12 is an explanation of a location of the crystal axis measurement apparatus, according to some embodiments;

FIG. 13 is a flowchart showing an example of an ion implantation method, according to some embodiments; and

FIG. 14-16 illustrate examples of an angle measurement apparatus, according to some embodiments.

### DETAILED DESCRIPTION

An actual ion beam irradiated onto a wafer does not always follow an ideal trajectory. In other words, there may be some errors between the actual trajectory of an ion beam irradiated onto the wafer and an ideal trajectory of the ion beam. For example, collisions between the ion beam and residual gas in a beamline can cause a charge conversion of the ion beam, which make it difficult to transport the ion beam along the ideal trajectory. Also, the ion beam trajectory can deviate from the ideal orbit due to factors such as a misarrangement of beam optical elements and manufacturing defects thereof.

One related art ion implantation process uses a channeling phenomenon. A crystal axis measurement apparatus is located in an end station or a load lock chamber of the ion implanter. Based on measurement results from the crystal axis measurement apparatus, a drive unit of a holding apparatus that holds a wafer in a process chamber is controlled.

The related art technique does not consider a discrepancy between the actual trajectory of the ion beam irradiated to the wafer and the ideal trajectory. Moreover, the positional relationship between the crystal orientation and the ion beam irradiation angle is adjusted only by the wafer drive unit in the process chamber.

Even if the related art technique has a means to measure the discrepancy between actual ion beam trajectory and ideal ion beam trajectory, there is concern that the configuration and control of the wafer drive unit will be complex.

Another related art technique identifies a crystal orientation of a wafer by calculating a cutting error of the wafer. Based on the identified crystal orientation of the wafer, one or more components, such as a mechanical scan drive and a beamline assembly, are selectively controlled in consideration of an effect of channeling.

The related art technique also obtains ion beam orientation data. One or more of the mechanical scan drive or beamline assembly are controlled to perform alignment of the irradiation angle of the ion beam onto the wafer surface, but there is no specific discussion of how the complex control is to be accomplished.

The beamline assembly of the related art is used for the purpose of ion beam transport. When the ion beam traveling direction is adjusted by the beamline assembly based on ion beam direction data, excessive control of the ion beam traveling direction makes it difficult to achieve the original purpose of ion beam transport (i.e., transporting the ion beam).

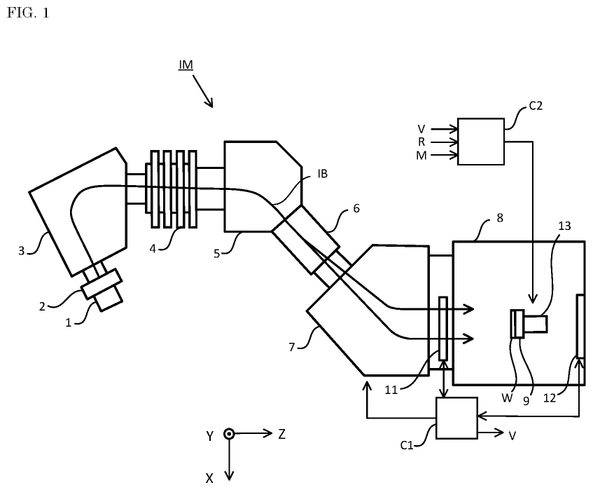

FIG. 1 is a schematic plan view of an example configuration of an ion implanter IM. The ion implanter IM may include a plasma chamber 1, an extraction electrode 2, a mass analyzer 3, an acceleration/deceleration tube 4, an energy filter 5, a scanner 6, a collimator 7, a process chamber 8, a wafer holder 9, front and back multipoint Faradays 11 and 12, and a drive device 13.

The plasma chamber 1 generates plasma, which is a source of an ion beam IB. The extraction electrode 2 extracts the ion beam IB from the plasma generated in the plasma chamber 1 into a beamline. The beamline is a transport path of the ion beam IB from the extraction electrode 2 to the process chamber 8.

The ion beam IB extracted from the extraction electrode 2 contains a plurality of ions. The mass analyzer 3, which is an electromagnet, selects the ions according to their mass to extract desired ions from the ion beam IB. The acceleration/deceleration tube 4 accelerates or decelerates the ion beam IB including ions selected by mass analyzer 3 to convert the ion beam IB into an ion beam IB having a desired energy.

The energy filter 5, which is an electromagnet, is located downstream of the acceleration/deceleration tube 4. The energy filter 5 removes ions with unnecessary energy components generated by charge conversion between the mass analyzer 3 and the acceleration/deceleration tube 4 or in the acceleration/deceleration tube 4.

When the ion beam IB is cut in a plane perpendicular to the traveling direction of ion beam, a cross-section of the ion beam IB extracted from the extraction electrode 2 is elliptical. Such an ion beam is called a spot beam.

After passing through the energy filter 5, the ion beam IB is periodically scanned along one direction by a scanner 6. This scanning converts the ion beam into an ion beam that is apparently wider in the scanning direction.

The scanned ion beam IB enters a collimator 7, and through magnetic deflection in the collimator 7, the ion beam IB is converted into a parallel ion beam IB in which the traveling direction of the ion beam IB passing through each location in the scanning direction of the ion beam IB is aligned. A width of the ion beam IB in the scanning direction after passing through the collimator 7 is wider than a width of a wafer W in the same direction. By moving the wafer holder 9 (and thus the wafer W) in a Y-axis direction, an ion implantation process is carried out on an entire surface of the wafer W. A wafer in this specification means a monocrystalline wafer, unless otherwise stated.

The wafer W held by the wafer holder 9 is placed in the process chamber 8. The drive device 13 is connected to the wafer holder 9. The drive device 13 adjusts a posture of the wafer holder 9 with respect to the ion beam IB to adjust an irradiation angle of the ion beam IB with respect to the wafer W.

The XYZ axes shown in FIG. 1 are drawn with respect to an ideal trajectory of the ion beam IB entering the process chamber 8. The Z axis is parallel to the traveling direction of the ion beam IB; the X and Y axes are mutually orthogonal to the Z axis. The direction of each of the XYZ axes varies according to the position of the ion beam being transported in the beamline. In the ion implanter IM, the scanning direction of the ion beam IB at the scanner 6 is parallel to the X axis.

In an embodiment, the ion implanter IM is equipped with an angle measurement apparatus that measures angles of the ion beam IB in two directions parallel to the X and Y axes. That is, the angle measurement apparatus measures a first angle of the ion beam IB in a first direction parallel to the X-axis and a second angle of the ion beam IB in a second direction parallel to the Y-axis. The angle measurement apparatus has the front multipoint Faraday 11 located between the collimator 7 and the process chamber 8 and the back multipoint Faraday 12 located in the process chamber 8. The angles of the ion beam IB means an angular difference between the ideal ion beam and the actual ion beam in the Z-axis.

Controllers C1 and C2 each include a processor and a memory. The processor may be a microprocessor, a central processing unit (CPU), a microcontroller, or hardware control logic, or some combination thereof. In some embodiments, the processor may be provided as a plurality of processors.

The memory of the controller C1 may store program code to implement various functions, such as, for example, a memory function to store data, an arithmetic function to calculate data, and a control function to control each part of the ion implanter IM based on the calculation results and based on input data. The processor of the controller C1 may access the program code stored in the memory of the controller C1 to perform the various functions. The structure and functions of the controller C2 are similar to the structure and function of the controller C2 and thus repeated description thereof is omitted for conciseness.

In an embodiment, the memory of the controller C1 may store measurement program code to implement a measurement function and adjustment program code to implement an adjustment function. The processor of the controller C1 may access the memory to execute the measurement program code to control the front multipoint faraday 11 and the back multipoint faraday 12 to read out measurement data therefrom and to output angle information V to the controller C2. The processor of the controller Cl may access the memory to execute the adjustment program code to adjust the magnetic field strength of the collimator 7 based on the angle information V.

In an embodiment, the memory of the controller C2 may store drive program code to implement a drive function. The processor of the controller C2 may access the memory to execute the drive program code to control the drive device 13 based on the angle information V, implantation recipe information R, and crystal axis information M. The ion implanter IM shown in FIG. 1 has separate controllers C1 and C2, but in some embodiments, the functions implemented by the controllers C1 and C2 may be combined into a single controller.

The implantation recipe information R contains information on a set angle of the wafer when the ion implantation process is performed. The crystal axis information M is information on an inclination angle of the crystal axis with respect to a direction perpendicular to the surface of the wafer W.

The crystal axis information M may be transmitted to the controller C2 by various methods. For example, in an embodiment, the crystal axis information M may be measured by a crystal axis measurement apparatus installed in the ion implanter IM, and the measured data may be transmitted to the controller C2 by a wired or wireless transmission method. In some embodiments, the crystal axis information M may be measured in a semiconductor manufacturing process upstream of the ion implantation process, and the measured data may be transmitted to the controller C2 by a wired or wireless transmission method. In some embodiments, the crystal axis information M may be included in a barcode attached to a wafer cassette, and the crystal axis information M may be acquired by reading the barcode by a barcode reader installed in the ion implanter IM, and the acquired information may be transmitted to the controller C2 by wire or wireless transmission method.

The acquisition of information from the barcode may be performed manually or automatically. In the manual case, an operator of the ion implanter IM may read the barcode with a scanner. In the automatic case, when the cassette is installed in the ion implanter IM, the barcode is read by a sensor/barcode reader in the installation position of the cassette. For automatic reading, the following configuration may be used. In some embodiments, the crystal axis information M for each wafer cassette or wafer may be stored in advance in the controller C1 and/or the controller C2. Based on the information of the cassette or wafer read from the barcode, the controller C1 and/or the controller C2 may read out the crystal axis information M that is stored.

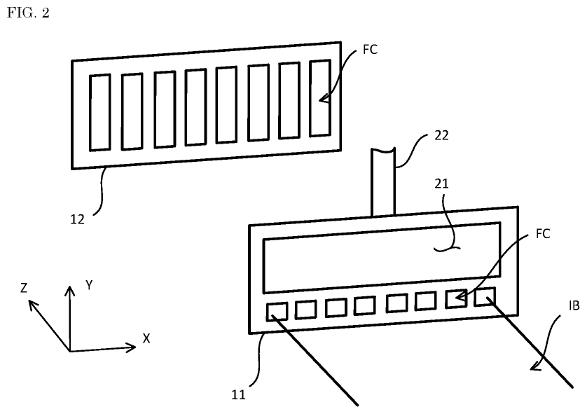

FIGS. 2 to 4 illustrate angular measurement of the ion beam IB in the X-axis direction. The front multipoint faraday 11 may be connected to a drive shaft 22. The drive shaft 22 is moved up and down in the Y-axis direction by a drive source (not shown). The front-multipoint faraday 11 has different configurations in the upper and lower regions in the Y-axis direction. The upper region has an aperture 21. The lower region has a plurality of Faraday cups FC arranged in the X-axis direction

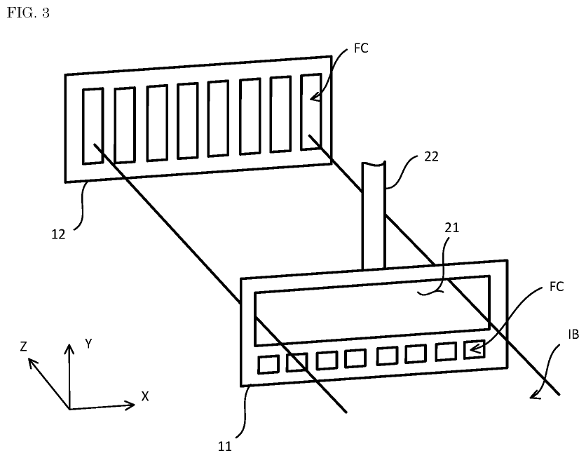

FIG. 2 shows an example of measurement at the front multipoint Faraday 11. The drive shaft 22 moves the front multipoint faraday 11 into the path of the ion beam IB, and the ion beam IB irradiates the faraday cups FC of the front multipoint faraday 11. FIG. 3 shows an example of measurement at the back multipoint faraday 12. From the state of the front multipoint faraday 11 shown in FIG. 2, the drive shaft 22 moves the front multipoint faraday 11 such that the ion beam IB passes through the aperture 21 of the front multipoint faraday 11. The ion beam IB that passes through the aperture 21 irradiates the faraday cups FC of the back multipoint faraday 12.

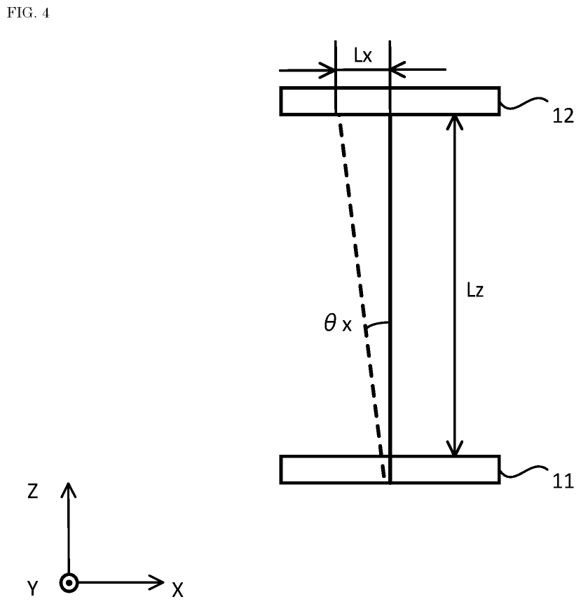

The following method is used as an example of calculating the irradiation angle of ion beam IB. As illustrated in FIG. 4, from both the measurement results of the front multipoint faraday 11 and the back multipoint faraday 12, the travel distance Lx of the ion beam IB in the direction of the X-axis is calculated. Using both the travel distance Lx and a separation distance Lz between the front-multipoint faraday 11 and the back multipoint faraday 12 in the direction of the Z-axis, the irradiation angle Ox of the ion beam IB in the X-axis direction may be calculated.

FIG. 4 shows the relationship between the travel distance Lx of the ion beam IB, the separation distance Lz between the front multipoint faraday 11 and the back multipoint faraday 12 in the z-axis direction, and the irradiation angle Ox of the ion beam IB. In FIG. 4, the dashed line shows the actual trajectory of the ion beam IB and the solid line shows the ideal trajectory of the ion beam IB. This calculation method is an example, and in some embodiments, a different calculation method may be used.

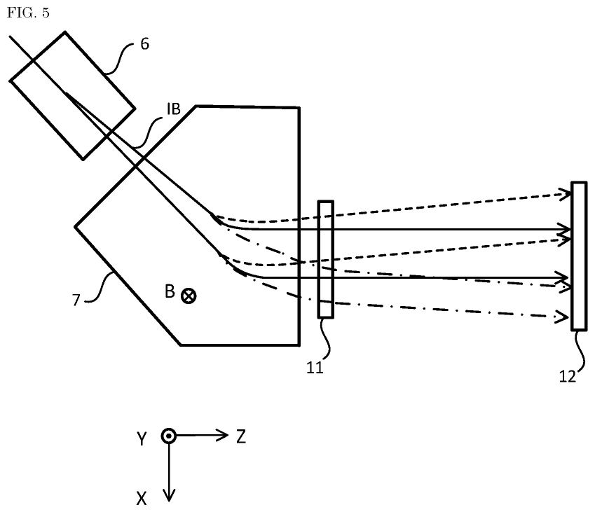

The irradiation angle of the ion beam IB in the X-axis direction is corrected by an angle corrector located in the beamline. In an embodiment, the collimator 7 of the ion implanter IM may double as the angle corrector. The collimator 7 is a kind of an electromagnet. By increasing or decreasing the amount of current flowing through a coil included in the collimator 7, the strength of the magnetic field B generated in the collimator 7 can be adjusted. When the ion beam IB passes through the magnetic field, the ion beam IB is deflected by the Lorentz force, as shown in FIG. 5. In the example illustrated in FIG. 5, the ion beam IB has a positive charge.

In FIG. 5, the solid line shows the ideal trajectory of the ion beam IB. When the strength of the magnetic field B of the collimator 7 is weakened, the ion beam IB is weakly deflected toward the lower side of the FIG. 5, as shown by the dash-dotted line. When the strength of the magnetic field B of the collimator 7 is increased, the ion beam IB is strongly deflected toward the upper side of the figure, as shown by the dashed line.

Based on the measurement results from the angle measurement apparatus, e.g., from the front multipoint Faraday 11 and the back multipoint Faraday 12, the magnetic field of the collimator 7 is adjusted to bring the trajectory of the ion beam IB closer to the ideal trajectory.

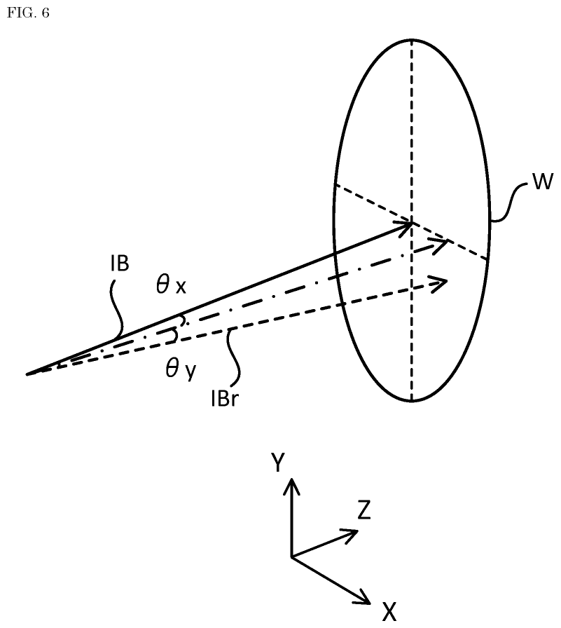

FIG. 6 illustrates a trajectory of the ion beam IB irradiating the wafer W. The solid line shows the ideal trajectory of the ion beam IB. The dashed line is the actual trajectory of the ion beam (i.e., the trajectory of ion beam IBr). The dashed-dotted line is the ion beam trajectory when the trajectory of the ion beam IBr is drawn on the X-axis assuming that the θy component is 0.

The XYZ axis directions shown in the FIG. 6 are drawn with respect to an ideal ion beam IB trajectory, as a reference trajectory. The ion beam IBr has an angular component (θx, θy) with respect to the reference trajectory. The angular component can be decomposed into a component in the x-axis and a component in the y-axis directions. When correcting the actual ion beam IB trajectory irradiated to the wafer W to the ideal trajectory, angular correction in the Y-axis direction and angular correction in the X-axis direction are used.

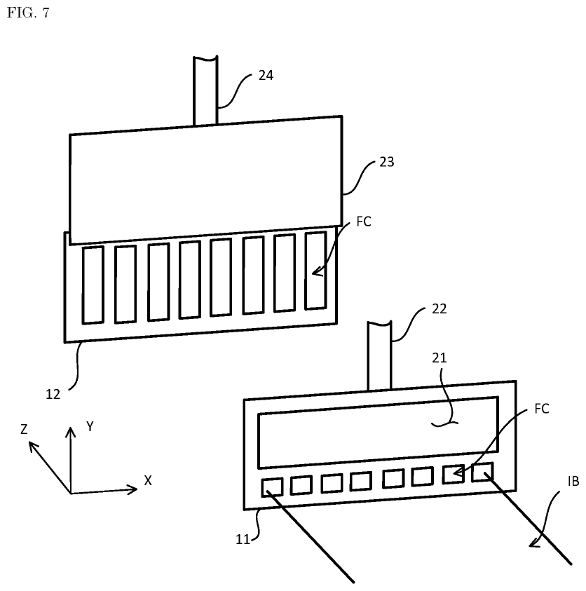

To correct the actual irradiation angle of the ion beam IBr in the Y-axis direction, the angle of the ion beam IBr in the Y-axis direction is measured. FIGS. 7 to 9 illustrate the angle measurement in the Y-axis direction.

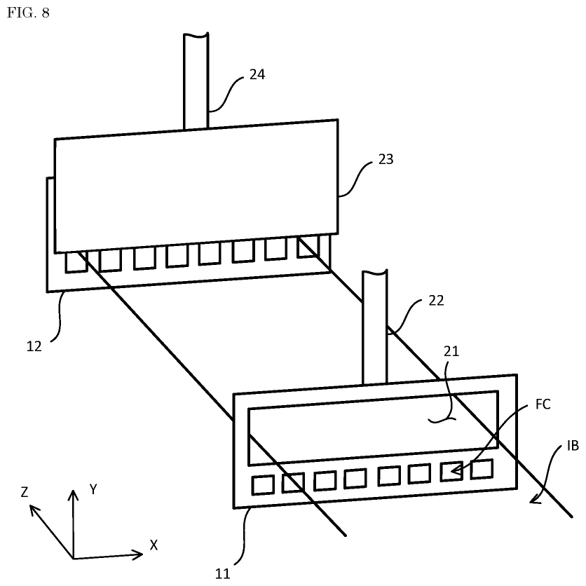

FIG. 7 and FIG. 8 illustrate the front multipoint faraday 11 and the back multipoint faraday 12 each having a similar configuration as the front multipoint faraday 11 and the back multipoint faraday 12 illustrated with respect to FIG. 2 and FIG. 3. One difference is that in FIG. 7 and FIG. 8, a shutter 23 that can move in the Y-axis direction is provided in front of the back multipoint faraday 12. The shutter 23 is connected to a shutter drive shaft 24 that moves in the vertical direction by a drive source (not shown).

An example of angle measurement in the Y-axis direction is explained based on FIG. 7 and FIG. 8. In FIG. 7, the beam current is measured at all Faraday cups FC in the front multipoint Faraday 11 while moving the front multipoint Faraday 11 into the path of the ion beam IM. Next, as shown in FIG. 8, the ion beam IB is irradiated to the Faraday cups FC of the back multipoint Faraday 12 by moving the front multipoint Faraday 11 so that the path of the ion beam IM passes through the aperture 21 of the front multipoint Faraday 11. Then, the shutter drive shaft 24 moves the shutter 23 downward, and the beam current is measured in all Faraday cups FC in the back multipoint Faraday 12.

From the measurement results at each multipoint faraday, the amount of change in the beam current at each measurement position is graphed, and the position of a center of gravity is calculated from the graph of the amount of change in the beam current. The irradiation angle θy of the ion beam in the Y-axis direction is calculated from the distance Ly between the center of gravity positions obtained from the measurement results at the front multipoint faraday 11 and the back multipoint faraday 12 and the separation distance Lz between the front multipoint faraday 11 and the back multipoint faraday 12 in the Z-axis direction.

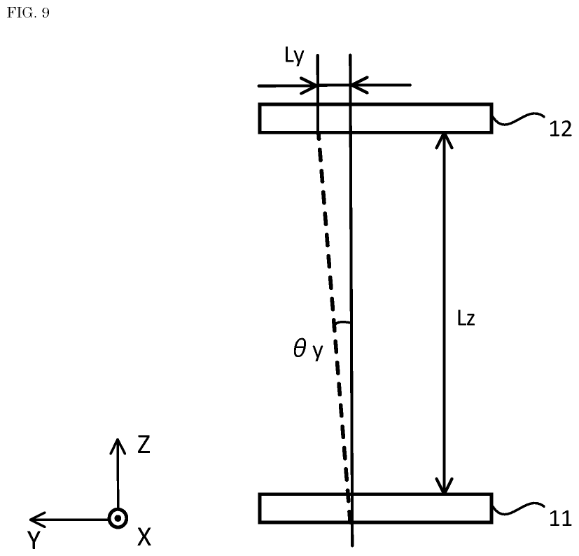

FIG. 9 shows the relationship between the distance Ly between the center of gravity positions, the separation distance Lz between the front multipoint faraday 11 and the back multipoint faraday 12 in the Z-axis direction, and the irradiation angle Oy of the ion beam IB, obtained from the measurements at the front multiple faraday 11 and the back multipoint faraday 12. In FIG. 9, the dashed line shows the actual trajectory of the ion beam IB and the solid line shows the ideal trajectory of the ion beam IB.

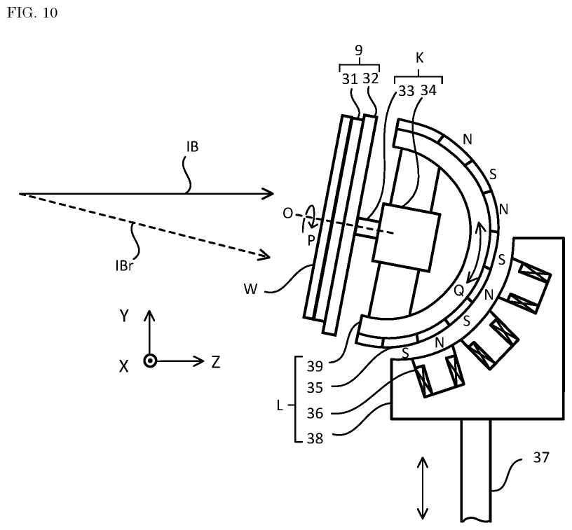

The ion beam irradiation angle in the Y-axis direction calculated in FIG. 7 and FIG. 8 is corrected by a tilt device L shown in FIG. 10.

FIG. 10 is a schematic cross-sectional view of an example of a tilt device for adjusting an orientation of a wafer in the Y-axis direction, according to some embodiments. The tilt device L includes a plurality of permanent magnets 35, a plurality of electromagnets 36, a pedestal 38 and a semicircular member 39. In FIG. 10, the solid line shows the ideal ion beam IB trajectory and the dashed line shows the actual ion beam IBr trajectory. The XYZ axis directions shown in the FIG. 10 are drawn with respect to the ideal ion beam IB trajectory. The wafer holder 9 includes a base 32 and an electrostatic chuck 31 that holds a rear surface (lower surface) of the wafer W.

The support of wafer W by electrostatic chuck 31 is advantageous in keeping the supported surface of wafer W flat. Although not shown in FIG. 10, in an embodiment, a mechanical clamp that mechanically holds the wafer W may be used in conjunction with the electrostatic chuck 31.

A rotary shaft 33 is attached to the center of the base 32, which coincides with the center O of the wafer W. The rotation shaft 33 is connected to a drive source 34. When the rotation shaft 33 is rotated by the drive source 34, the base 32 connected to the rotation shaft 33 rotates. As the base 32 rotates, the wafer holder 9 rotates and thus the wafer W rotates in a circumferential direction (in the direction of arrow P). The rotation adjusts the position of the wafer W in the circumferential direction. The rotary shaft 33 and drive source 34, which together adjust the position of the wafer W in the circumferential direction, are called a twist device K.

In some embodiments, the direction of rotation of the wafer W by the twist device K may be opposite to the arrow P shown in the FIG. 10. By switching the direction of rotation at the drive source 34, the wafer W may be configured to rotate reversibly. The drive source 34 may be fixed to the semi-circular member 39. The semi-circular member 39 includes the plurality of permanent magnets 35 on a periphery of the semi-circular member 39. The pedestal 38 has a curved portion that follows the semi-circular shape of the semi-circular member 39. The pedestal 38 is located opposite the semi-circular member 39. The plurality of electromagnets 36 are arranged on the curved portion of the pedestal 38.

By adjusting the direction and magnitude of the current flowing to the electromagnets 36 on the pedestal 38, the semi-circular member 39 is slid in one of the directions indicated by arrow Q. The sliding of the semi-circular member 39 rotates the wafer W around the X-axis and adjusts the irradiation angle of the ion beam IBr with respect to the wafer W.

By rotating the wafer W around the X-axis with the tilt device L, the irradiation angle of the ion beam IB in the Y-axis direction may be corrected. The pedestal 38 is connected to a wafer drive shaft 37, and by moving the wafer drive shaft 37 up and down by a drive source (not shown), the ion implantation process may be performed on the wafer W.

For the crystal axis measurement apparatus, in an embodiment, an X-ray diffractometer may be used. The X-ray diffractometer may detect reflected or transmitted light from the wafer. In some embodiments, a configuration that sequentially changes the detection position using an actuator or a configuration with a two-dimensionally arrayed detection area may be used.

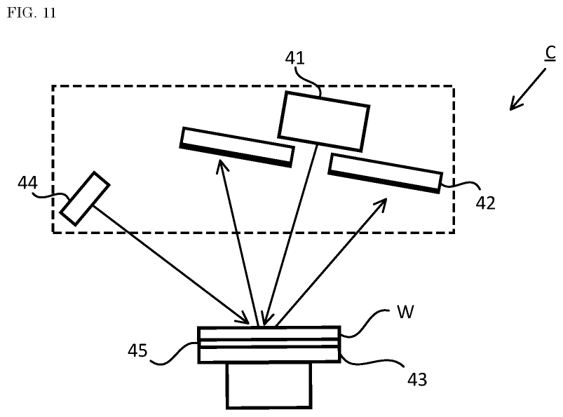

FIG. 11 shows a schematic plan view of a crystal axis measurement apparatus C, according to some embodiments. The crystal axis measurement apparatus C may use a back reflection Laue method. In an embodiment, the crystal axis measurement apparatus C may include an energy beam source 41, a detector 42, a measurement table 43, an imaging device 44, and an adsorption member 45. X-rays are irradiated from the energy beam source 41 to a wafer W placed on the measurement table 43. In an embodiment, the detector 42 may be an imaging plate with openings through which X-rays pass. The detector 42 receives the reflected light from the wafer W and detects the X-ray diffraction image. In detecting with the detector 42, a laser beam (not shown) may be irradiated to the light receiving surface of the detector 42 to adjust the detected signal intensity.

The imaging device 44 has an imaging lens and takes diffraction images. The crystal axis measurement apparatus C may include an arithmetic unit, for example, a processor or central processing unit (CPU), and the arithmetic unit analyzes the captured image data to identify the crystal orientation. Each of the parts enclosed by the dashed lines may be configured as a single unit. An actuator to change the position of either the measurement table 43 (i.e., the wafer W) or the single unit may be provided to allow adjustment of the relative position of the wafer W and the single unit. If diffraction images can be obtained with the imaging plate, the imaging device 44 may be omitted in some embodiments.

When semiconductor manufacturing process is applied to wafers W, wafer W may be warped to some extent. If crystal orientation measurement is performed on a warped wafer W, exact measurement of the crystal orientation becomes impossible. It is said that the area near the center of wafer W is relatively less susceptible to warpage. Therefore, for exact crystal orientation measurement, it is advantageous to irradiate energy beams near the center of wafer W to perform crystal orientation measurement.

In terms of measuring crystal orientation more exactly regardless of the measurement near the center of the wafer, it is advantageous to have the adsorption member 45 on the measurement table 43 where the wafer is placed in the crystal axis measurement apparatus C. By adsorbing the wafer W with the adsorption member 45, the flatness of the wafer W is improved. By performing crystal orientation measurement on the wafer W with improved flatness, the result of the measurement becomes more exact. Examples of the adsorption member 45 include an electrostatic chuck or a vacuum adsorption member. When the electrostatic chuck is used, a chucking force should be the same as that of the electrostatic chuck 31 of the wafer holder 9 that will be used during ion implantation.

In some embodiments, the crystal axis measurement apparatus may be an apparatus that identifies the crystal orientation by irradiating a wafer W with natural or laser light from the energy source such as a mercury vapor lamp, halogen lamp, or helium-neon laser, and monitoring the transmitted or reflected light from the wafer W.

In some embodiments, the crystal orientation may be identified by Rutherford backscattering analysis using an ion beam. In some embodiments, the crystal orientation may be identified from a graph of a relationship between an irradiation angle and wafer characteristics (sheet resistance, residual defects, etc.) after performing ion implantation processing on the wafer while changing the irradiation angle of the ion beam.

The wafer W used to identify the crystal orientation may be a test wafer, rather than the wafer W on which the ion implantation process is performed. As the test wafer, a wafer W in the same lot as the wafer W to which the ion implantation process is applied may be used. The measurement results on the test wafer are stored in the ion implanter IM as crystal axis information M. When wafer W in the same lot is processed, the measurement data are read out and used as appropriate during the ion implantation process in the ion implanter IM. In some embodiments, a first wafer to be processed in the same lot may be used as a test wafer, and the ion implantation process may be performed on this wafer. In other words, the first wafer in a lot may be used as the test wafer, and the ion implantation process may be performed on the remaining wafers of the lot.

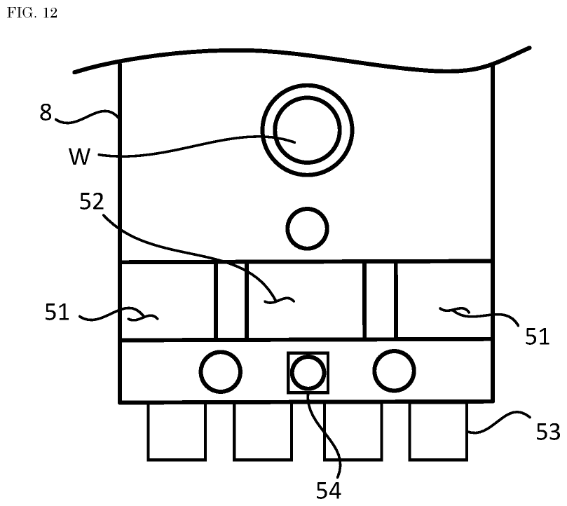

FIG. 12 illustrates a configuration of a ion implanter IM around the process chamber 8, according to some embodiments. When the crystal axis measurement apparatus C is mounted on the ion implanter IM, the crystal axis measurement apparatus C may be placed in the process chamber 8 if maintenance of the crystal axis measurement apparatus C is not considered. In that case, the wafer holder 9 can be used as the measurement table 43.

In addition to process chamber 8, the crystal axis measurement apparatus C may be placed in a load lock chamber 51 or at the location where an aligner 54 is placed. When the crystal axis measurement apparatus C is placed in the load lock chamber 51 or the aligner 54 locations, the support of wafer W that originally exists in the load lock chamber 51 or the aligner 54 locations can be used as the measurement table 43 as in the case of process chamber 8.

In some embodiments, the crystal axis measurement chamber 52 may be provided as a special chamber for crystal orientation measurement. In FIG. 12, the location of the crystal axis measurement chamber 52 is adjacent to the process chamber 8, but embodiments are not limited to this location. The crystal axis measurement chamber 52 may be located next to, above or below where the aligner 54 is located.

In some embodiments, the crystal axis measurement apparatus C may be placed at the location where cassettes 53 in which wafer W is stored are placed. Specifically, one of the four cassettes 53 shown in FIG. 12 may be eliminated, and the crystal axis measurement apparatus C may be placed at the location where the cassette 53 is eliminated.

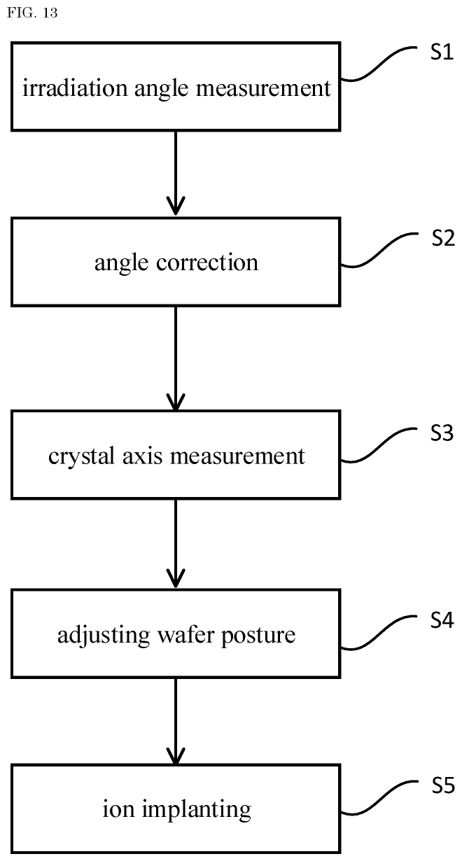

The flowchart in FIG. 13 shows an example of an ion implantation process, according to some embodiments. The irradiation angle of the ion beam is measured with an angle measurement apparatus in two directions (X-axis and Y-axis directions) that are mutually perpendicular to the direction of ion beam travel (S1). An angle corrector located in the beamline corrects one of the ion beam irradiation angles measured by the angle measurement apparatus (S2). The crystal axis direction of the wafer W is measured by the crystal axis measurement apparatus (S3). In some embodiments, the measurement of the crystal orientation at the ion implanter IM may be omitted. Measurement of the crystal orientation may be implemented by transmitting the crystal axis information measured by an apparatus other than the ion implanter IM to the ion implanter IM or by acquiring the crystal axis information from the barcode attached to the cassette, as discussed above. The process S3 may be performed before the process S1 or between the process S1 and the process S2, depending on the configuration of the apparatus.

Based on the ion beam angle information that have not been corrected in the process S2, crystal axis information and implantation recipe information, a posture of the wafer W to be targeted is calculated. The posture of the wafer W is adjusted using the tilt device L based on the calculation results (S4). After the adjustment is completed, the ion implantation process to the wafer W is performed (S5).

According to various embodiments, a deviation between the actual and ideal ion beam travel direction is decomposed into angular components in two orthogonal directions, and correction of one angular component is performed at the beamline, and correction of the other angular component is performed at the wafer holder 9 in consideration of the crystal axis information and implantation recipe information.

According to various embodiments, angle correction at the beamline is only for one direction, so the configuration and control of optical elements can be simplified, and the effect of angle correction at the beamline on transport of the ion beam is small and limited.

Remaining angle correction of the ion beam is performed by the wafer holder 9, considering the crystal axis information and the implantation recipe information. Since remaining angle correction of the ion beam only uses correction in a specific direction, the structure and control of the wafer holder 9 can be made much simpler than when all corrections are performed by the wafer holder 9.

By performing ion implantation under such a configuration, the ion implantation process can be achieved at desired angle to the wafer with high precision, without interfering with ion beam transport and reducing the burden on the wafer drive unit side.

In the above embodiment, the ion implanter IM is assumed to be a single-wafer ion implanter that uses a spot beam, but in some embodiments, the ion implanter IM can also be applied to a batch-type ion implanter with a disk that holds multiple wafers. In some embodiments, the ion beam may be a non-scanning ribbon beam instead of a spot beam. In some embodiments, the configuration of the ion implanter IM can also be switched between the X-axis and Y-axis. In this case, the ion beam is scanned in the Y-axis direction and the wafer holder 9 is driven in the X-axis direction to perform the ion implantation process on the wafer

W. The rotation axis of the wafer W by the tilt device L may be the Y-axis.

Controllers C1 and/or C2 may make a crystal axis of the wafer parallel to the traveling direction of the ion beam by the tilt device L to perform channeling ion implantation.

In adjusting the posture of wafer W in process S4 of FIG. 13, the adjustment using the twist device K, which is not related to the angle correction in embodiment of FIG. 13, is omitted. In the actual ion implantation process, if it is necessary to set the twist angle, the adjustment using twist device K should be done when adjusting the posture of the wafer W using the tilt device L in process S4.

In some embodiments, a configuration using the front multipoint faraday 11 and the back multipoint faraday 12 as angle measurement apparatus is described, but in some embodiments, other configurations may be used if they can measure the angle of the ion beam in two orthogonal directions (X-axis and Y-axis directions). The two orthogonal directions may be measured using independent angle measurement apparatuses (i.e., two separate angle measurement apparatuses), and there is no restriction on the number of angle measurement apparatus used for angle measurement.

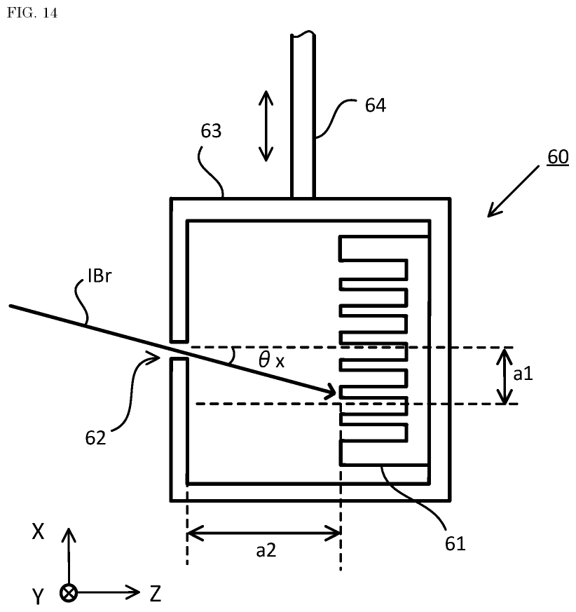

FIGS. 14-16 show examples of angle measurement apparatuses, according to various embodiments. FIG. 14 shows a schematic cross-sectional view of an angle measurement apparatus 60, according to an embodiment. The angle measurement apparatus 60 has a box 63 that integrates a multipoint Faraday 61 including a plurality of Faraday cups and a flat plate with a slit 62. Slit 62 is long in the Y-axis direction. The box 63 is connected to a drive shaft 64. By moving the drive shaft 64 in the arrow direction by a drive source (not shown), the box 63 connected to the drive shaft 64 is moved in and out of the ion beam IB irradiation area.

The multipoint Faraday 61 is used to detect the beam current of the ion beam IBr irradiated through the slit 62 into the box 63. The position of the Faraday cup where the detected beam current is maximum is identified, and the irradiation angle Ox of the ion beam IBr in the X-axis direction is calculated from the distance al between the identified Faraday cup and the slit 62 and the distance a2 between the multipoint Faraday 61 and the slit 62.

In FIG. 14, the directions of the X and Y axes may be interchanged to calculate the irradiation angle of the ion beam IBr in the Y-axis direction. In this case, the direction of movement of the angle measurement apparatus 60 and the alignment of the faraday at the multipoint faraday 61 will be in the Y-axis direction. The longitudinal direction of the slit 62 is the X-axis direction. In some embodiments, pinholes may be used instead of slits, including in the angle measurement apparatuses described below.

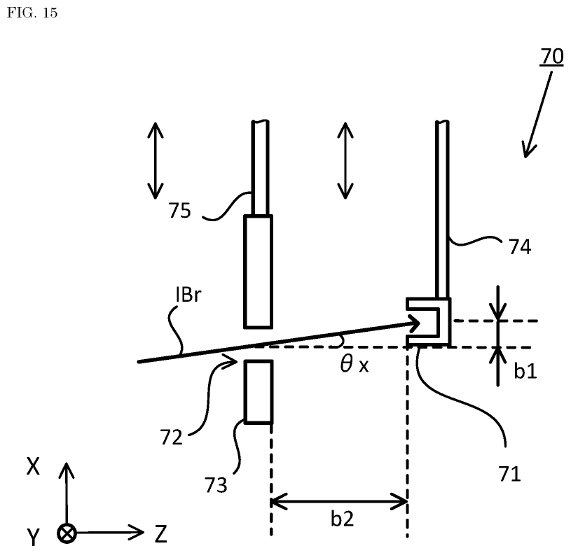

FIG. 15 shows a schematic cross-sectional view of an angle measurement apparatus 70, according to an embodiment. The angle measurement apparatus 70 has a flat plate 73 with a slit 72 and a Faraday cup 71. The flat plate 73 is connected to a drive shaft 75. Faraday cup 71 is connected to a drive shaft 74. Two drive shafts 74 and 75 move the flat plate 73 and the Faraday cup 71 as shown by the arrows in FIG. 15. The flat plate 73 is placed at a predetermined position in the irradiation area of the ion beam IBr. The Faraday cup 71 is then moved in a direction parallel to the flat plate 73 (X-axis direction). The beam current of the actual ion beam IBr passing through the slit 72 is detected, and the position where the detected beam current is maximum is identified. The distance b1 from the identified position to the center position of the slit 72 in the X-axis direction is calculated. From the calculated distance b1 and the distance b2 between the slit 72 and the Faraday cup 71, the irradiation angle Ox of the ion beam IBr passing through the slit 72 is calculated.

The irradiation angle of ion beam IBr in the Y-axis direction can be calculated if the relationship between the X and Y axes is opposite in the implementation of FIG. 15.

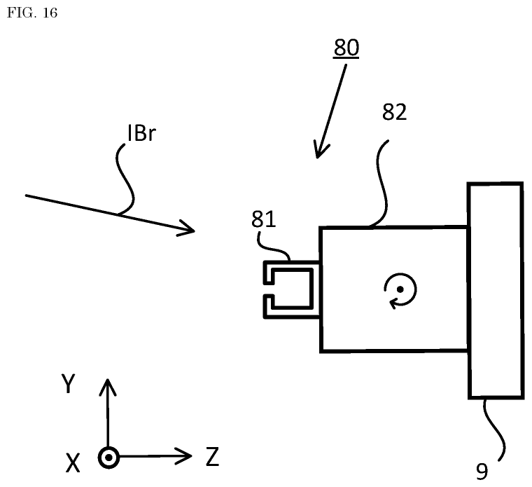

FIG. 16 shows a schematic cross-sectional view of an angle measurement apparatus 80, according to an embodiment. The angle measurement apparatus 80 has a drive device 82 and a Faraday cup 81 located at one end of the drive device 82. The drive device 82 rotates around a rotation axis parallel to the X-axis. While rotating the drive device 82, the rotation angle of the drive device 82 is identified when the beam current of the actual ion beam IBr is maximum at the Faraday cup 81. Faraday cup 81 and wafer holder 9 are mounted at a predetermined angle to drive device 82. By identifying the rotation angle of the drive device 82 when the beam current is at its maximum, the irradiation angle of the ion beam to the wafer can be determined.

In the ion implantation process, after holding a wafer (not shown in FIG. 16) in the wafer holder 9, the drive device 82 is rotated to swap the positions of the wafer holder 9 and the Faraday cup 81 from those shown in FIG. 16.

The rotation angle of drive device 82 is advantageously 360 degrees. However, embodiments are not limited thereto. In some embodiments, the rotation angle of the drive device 82 can be less than 360 degrees if each of the following processes can be performed: measurement with the Faraday cup 81, ion implantation process to the wafer W, and switching the positions of the Faraday cup 81 and the wafer holder 9.

A configuration using a collimator 7 as an angle corrector is described above, but in some embodiments, an optical element for angle correction may be placed in the beamline. In the ion implanter IM of FIG. 1, the acceleration/deceleration tube 4 has a focus lens that corrects the diameter of the ion beam passing through the acceleration/deceleration tube 4. In some embodiments, the focus lens is an optical element known as a quadrupole lens, which may be used as an angle corrector.

In some embodiments, an energy filter has a pair of electrodes may be used as an angle corrector. All optical elements listed here can adjust the angle of the ion beam IB in the X-or Y-axis. Other optical elements with similar functions may be used.

It should be understood that embodiments are not limited to the various embodiments described above, but various other changes and modifications may be made therein without departing from the spirit and scope thereof as set forth in appended claims.

What is claimed is:

1. An ion implanter comprising:
an angle measurement apparatus that measures a first angle of an ion beam in a first direction and a second angle of the ion beam in a second direction, the first direction and the second direction being mutually orthogonal to a traveling direction of the ion beam;
an angle corrector that is located in a beamline of the ion beam and corrects an angle of the ion beam in the first direction based on the first angle;
a wafer holder that holds a wafer in a process chamber;
a tilt device that is connected to the wafer holder and that rotates the wafer around a rotation axis parallel to the first direction; and
a controller that controls the tilt device based on the second angle, crystal axis information of the wafer, and implantation recipe information.

1. on implanter as recited in claim 1, wherein the ion beam is a spot beam that is scanned in the first direction and the angle corrector is a collimator that deflects the scanned spot beam.

3. The ion implanter as recited in claim 2, wherein the wafer holder comprises an electrostatic chuck that holds a lower surface of the wafer.

4. The ion implanter as recited in claim 2, further comprising:
a measurement table comprising an adsorption member that supports a rear surface of the wafer, and
a crystal axis measurement apparatus including an energy beam source that irradiates energy beams onto a top surface of the wafer that is supported by the measurement table.

5. The ion implanter as recited in claim 4, wherein the adsorption member is an electrostatic chuck.

6. The ion implanter as recited in claim 1, wherein the wafer holder comprises an electrostatic chuck that holds a rear surface of the wafer.

7. The ion implanter as recited in claim 1, further comprising:
a measurement table comprising an adsorption member that supports a rear surface of the wafer, and
a crystal axis measurement apparatus including an energy beam source that irradiates energy beams onto a top surface of the wafer that is supported by the measurement table.

7. on implanter as recited in claim 7, wherein the adsorption member is an electrostatic chuck.

9. The ion implanter as recited in claim 1, wherein the beamline is a transport path of the ion beam from an extraction electrode to the process chamber of the ion implanter.

10. The ion implanter as recited in claim 1, wherein the controller controls the tilt device to make a crystal axis of the wafer parallel to the traveling direction of the ion beam.

11. An ion implantation method comprising:
measuring a first angle of an ion beam in a first direction and a second angle of the ion beam in a second direction, the first direction and the second direction being mutually orthogonal to a traveling direction of the ion beam;
correcting an angle of the ion beam in the first direction based on the first angle;
rotating the wafer with the first direction as a rotation axis based on the second angle, crystal axis information of the wafer, and implantation recipe information, and
implanting ions into the wafer.

12. An ion implanter comprising:
a plasma chamber;
one or more extraction electrodes that extract an ion beam from the plasma chamber;
a process chamber comprising a wafer holder and a tilt device;
an angle measurement apparatus that measures angles of the ion beam in two directions that are mutually orthogonal to a traveling direction of the ion beam;
an angle corrector that is located in a beamline of the ion beam and corrects an angle of the ion beam in one of the two directions based on the measured angle in the one of the two directions, the beamline being a transport path of the ion beam from the one or more extraction electrodes to the process chamber; and
a controller that controls the tilt device based on the measured angle in the other of the two directions, crystal axis information of the wafer, and implantation recipe information to correct an angle of the ion beam in the other of the two directions.

13. The ion implanter as recited in claim 12, wherein the ion beam is a spot beam that is scanned in the one of the two directions and the angle corrector is a collimator that deflects the scanned spot beam.

14. The ion implanter as recited in claim 13, wherein the wafer holder comprises an electrostatic chuck that holds a rear surface of the wafer.

15. The ion implanter as recited in claim 13, further comprising:
a measurement table comprising an adsorption member that supports a rear surface of the wafer, and
a crystal axis measurement apparatus including an energy beam source that irradiates energy beams onto a top surface of the wafer that is supported by the measurement table.

16. The ion implanter as recited in claim 15, wherein the adsorption member is an electrostatic chuck.

17. The ion implanter as recited in claim 12, wherein the wafer holder comprises an electrostatic chuck that holds a lower surface of the wafer.

18. The ion implanter as recited in claim 12, further comprising:
a measurement table comprising an adsorption member that supports a rear surface of the wafer, and
a crystal axis measurement apparatus including an energy beam source that irradiates energy beams onto a top surface of the wafer that is supported by the measurement table.

19. The ion implanter as recited in claim 18, wherein the adsorption member is an electrostatic chuck.

20. The ion implanter as recited in claim 12, wherein the controller controls the tilt device to make a crystal axis of the wafer parallel to the traveling direction of the ion beam.
